(19) United States
(12) Patent Application Publication
(10) Pub. No.: US 2016/0217970 A1
(43) Pub. Date: Jul. 28, 2016

(54) ION IMPLANTER AND METHOD FOR ION IMPLANTATION

(71) Applicant: ADVANCED ION BEAM TECHNOLOGY, INC., Hsinchu (TW)

(72) Inventors: Anwar HUSAIN, Pleasanton, CA (US); Valeriy LITVAK, Los Gatos, CA (US)

(21) Appl. No.: 14/607,867

(22) Filed: Jan. 28, 2015

(51) Int. Cl. H01J 37/20; H01J 37/18; H01L 21/265; H01J 37/317

(52) U.S. Cl. CPC H01J 37/20; H01J 37/3171; H01J 37/185; H01L 21/265

(57) ABSTRACT

An ion implanter comprising a process chamber, a FOUP and a temperature treating assembly and a method using the same are provided. A workpiece can be implanted according to a recipe of an ion implantation in the process chamber. The FOUP can transfer a workpiece toward and away from the process chamber. The temperature treating assembly comprises a vacuum chamber, a heating module and a cooling module. The vacuum chamber communicates with the process chamber and has a heating space and a cooling space next to the heating space. The heating module is mounted on the vacuum chamber from a side of the heating space for heating the workpiece located in the heating space to a first temperature. The cooling module is mounted in the cooling space for cooling the workpiece located in the cooling space to a second temperature different from the first temperature.

### FIELD OF THE INVENTION

The present invention generally relates to an ion implanter and a method for an ion implantation, and more particularly to an ion implanter and a method for an ion implantation for previously and/or posteriorly adjusting a temperature of a workpiece to meet a recipe of the ion implantation.

### DESCRIPTION OF THE RELATED ART

Ion implantation is a very important technique for the manufacture of semiconductors, such as integrated circuit (IC), memory, flat plan display (FPD), solar cell and so on, which is used to dope impurities into a workpiece, such as a silicon wafer, a glass plate and so on, with an ion implanter. In addition, the accuracy of performing the ion implantation significantly influences on yielding rate of the manufacture. However, most of the researches of the ion implantation focus on ways to scan a workpiece instead of the temperature control before and after scanning the workpiece.

For example, the temperature of the workpiece is increased during the ions provided by an ion implanter continuously impinging onto the workpiece. However, the conventional ion implanters usually cool the workpiece by merely leaving the workpiece in a load lock till its temperature is decreased to a room temperature without using any cooler or chiller, so that a throughput of the ion implantation is significantly reduced. Furthermore, in some specific cases, heating or cooling a workpiece before it is implanted may increase the total accuracy of performing the ion implantation. However, the conventional ion implanters are usually designed without any heater or cooler for previously heating/cooling the workpiece to meet a recipe of the ion implantation. As a result, it is desired to provide a new ion implantation method for previously and/or posteriorly adjusting a temperature of a workpiece to meet the recipe of the ion implantation and a new ion implanter for practicing that ion implantation method.

### SUMMARY OF THE INVENTION

The present invention is directed to an ion implanter and a method for an ion implantation for previously and/or posteriorly adjusting a temperature of a workpiece to meet a recipe of the ion implantation.

The present invention provides an ion implanter comprising a process chamber, a

FOUP and a temperature treating assembly. A workpiece can be implanted according to a recipe of an ion implantation in the process chamber. The FOUP (front opening unified pod) can transfer a workpiece toward and away from the process chamber. The temperature treating assembly comprises a vacuum chamber, a heating module and a cooling module. The vacuum chamber communicates with the process chamber and has a heating space and a cooling space next to the heating space. In addition, the heating module is mounted on the vacuum chamber from a side of the heating space for heating the workpiece located in the heating space to a first temperature, while the cooling module is mounted in the cooling space for cooling the workpiece located in the cooling space to a second temperature different from the first temperature.

According to an embodiment of the present invention, the ion implanter further comprises a load lock located between the FOUP and the process chamber for passing the workpiece between an ambient condition and a vacuum condition.

According to an embodiment of the present invention, the ion implanter further comprises an arm for transferring the workpiece between the process chamber and the vacuum chamber.

According to an embodiment of the present invention, the temperature treating assembly further comprises a partition for separating the heating space from the cooling space.

According to an embodiment of the present invention, the heating module comprises a housing, at least a heater arranged in the housing and a quartz window covering the housing for separating the heater from the heating space. According to a specific embodiment, the heater can comprise at least an IR lamp or a heating wire. In addition, according to another specific embodiment, the heating module can further comprise a reflector located on an inner surface of the housing, so as to reflect the heat flux provided by the heater toward the quartz window. Furthermore, according to one more specific embodiment, the heating module can further comprise a shield element arranged between the heater and the quartz window, so as to spread the heat flux provided by the heater toward the quartz window.

According to an embodiment of the present invention, the cooling module comprises an ESC (electro static chuck) mounted in the cooling space for holding the workpiece, a chiller disposed outside the vacuum chamber, and a coolant line connecting the ESC to the chiller, so as to chill the ESC by the chiller via the coolant line. According to a specific embodiment, the cooling module can further comprise a thermistor disposed on the ESC for monitoring a temperature of the ESC.

According to an embodiment of the present invention, the cooling module further comprises a sensor disposed in the cooling space for detecting a position of the workpiece.

According to an embodiment of the present invention, one of the first temperature and the second temperature is treated to meet a requirement of the recipe before the workpiece is implanted, while the other one of the first temperature and the second temperature is treated to meet the room temperature before the workpiece is returned to the FOUP.

The present invention further provides a method for an ion implantation comprising the following steps. First, a workpiece transferred from a FOUP is pre-heated to a first temperature to meet a recipe of the ion implantation. Afterward, the workpiece is implanted according to the recipe. Next, the workpiece is post-cooled to a second temperature lower than the first temperature before being returned to the FOUP.

According to an embodiment of the present invention, the first temperature is significantly higher than a room temperature, while the second temperature is substantially equal to the room temperature.

According to an embodiment of the present invention, the step for pre-heating the workpiece is treated in a heating space of a vacuum chamber communicating with a process chamber for the recipe.

According to an embodiment of the present invention, the step for pre-heating the workpiece comprises warming the workpiece by at least a heater. According to a specific embodiment, the heater can comprise at least an IR lamp or a heating wire.

According to an embodiment of the present invention, the step for post-cooling the workpiece is treated in a cooling space of a vacuum chamber communicating with a process chamber for the recipe.

According to an embodiment of the present invention, the step for post-cooling the workpiece comprises chilling an ESC by a chiller via a coolant line connected therebetween.

According to an embodiment of the present invention, the method further comprises a step for passing the workpiece from an ambient condition to a vacuum condition in a load lock before pre-heating the workpiece.

According to an embodiment of the present invention, the method further comprises a step for passing the workpiece from a vacuum condition to an ambient condition in a load lock before returned the workpiece to the FOUP.

The present invention also provides a method for an ion implantation comprising the following steps. First, a workpiece transferred from a FOUP is warmed by at least a heater, so as to pre-heat the workpiece to a first temperature to meet a recipe of the ion implantation. Next, the workpiece is transferred to a process chamber for the recipe. Then, the workpiece is implanted according to the recipe in the process chamber. Afterward, an ESC is chilled by a chiller via a coolant line connected between the ESC and the chiller, so as to post-cool the workpiece to a second temperature lower than the first temperature. Thereafter, the workpiece is returned to the FOUP.

According to an embodiment of the present invention, the first temperature is significantly higher than a room temperature, while the second temperature is substantially equal to the room temperature.

According to an embodiment of the present invention, the step for pre-heating the workpiece is treated in a heating space of a vacuum chamber communicating with a process chamber.

According to an embodiment of the present invention, the heater comprises at least an IR lamp or a heating wire.

According to an embodiment of the present invention, the step for post-cooling the workpiece is treated in a cooling space of a vacuum chamber communicating with the process chamber.

According to an embodiment of the present invention, the method further comprises a step for passing the workpiece from an ambient condition to a vacuum condition in a load lock before pre-heating the workpiece.

According to an embodiment of the present invention, the method further comprises a step for passing the workpiece from a vacuum condition to an ambient condition in a load lock before returned the workpiece to the FOUP.

Accordingly, a workpiece can not only be pre-cooled to meet a recipe of a low temperature implantation and post-heated before being returned to the FOUP to prevent the moisture in the atmosphere from condensing onto the wafer, but also be pre-heated to meet a recipe of a high temperature implantation and post-cooled before being returned to the FOUP to significantly increase a throughput of the ion implantation by using the ion implanter and the method for an ion implantation provided in the present invention.

### BRIEF DESCRIPTION OF THE DRAWINGS

FIG. 1 illustrates a schematic view of an ion implanter according to an embodiment of the present invention.

FIG. 2 illustrates a cross-sectional view of the temperature treating assembly as shown in FIG. 2.

FIG. 3 illustrates a top view of the shield element as shown in FIG. 3.

FIG. 4 illustrates a flow chart of a method for an ion implantation according to an embodiment of the present invention.

### DETAILED DESCRIPTION OF THE INVENTION

Reference will now be made in detail to specific embodiments of the present invention. Examples of these embodiments are illustrated in the accompanying drawings. While the invention will be described in conjunction with these specific embodiments, it will be understood that it is not intended to limit the invention to these embodiments. In fact, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations are not described in detail in order not to obscure the present invention. Besides, in all of the following embodiments, the same or similar components illustrated in different embodiments refer to the same symbols.

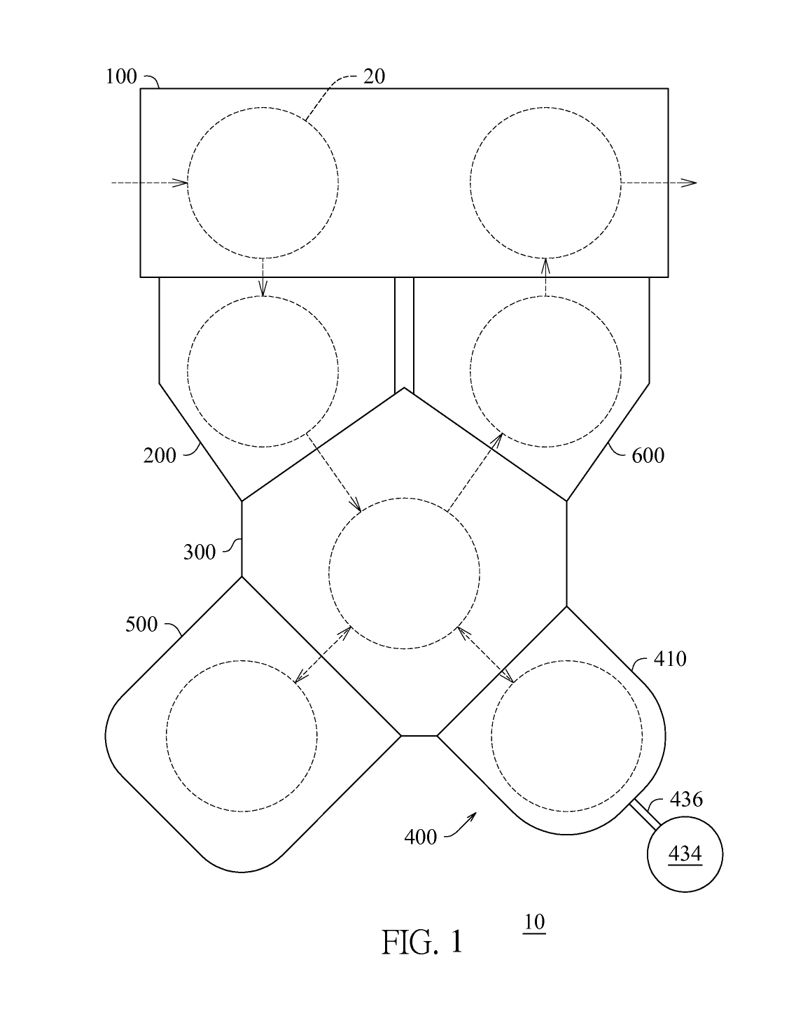

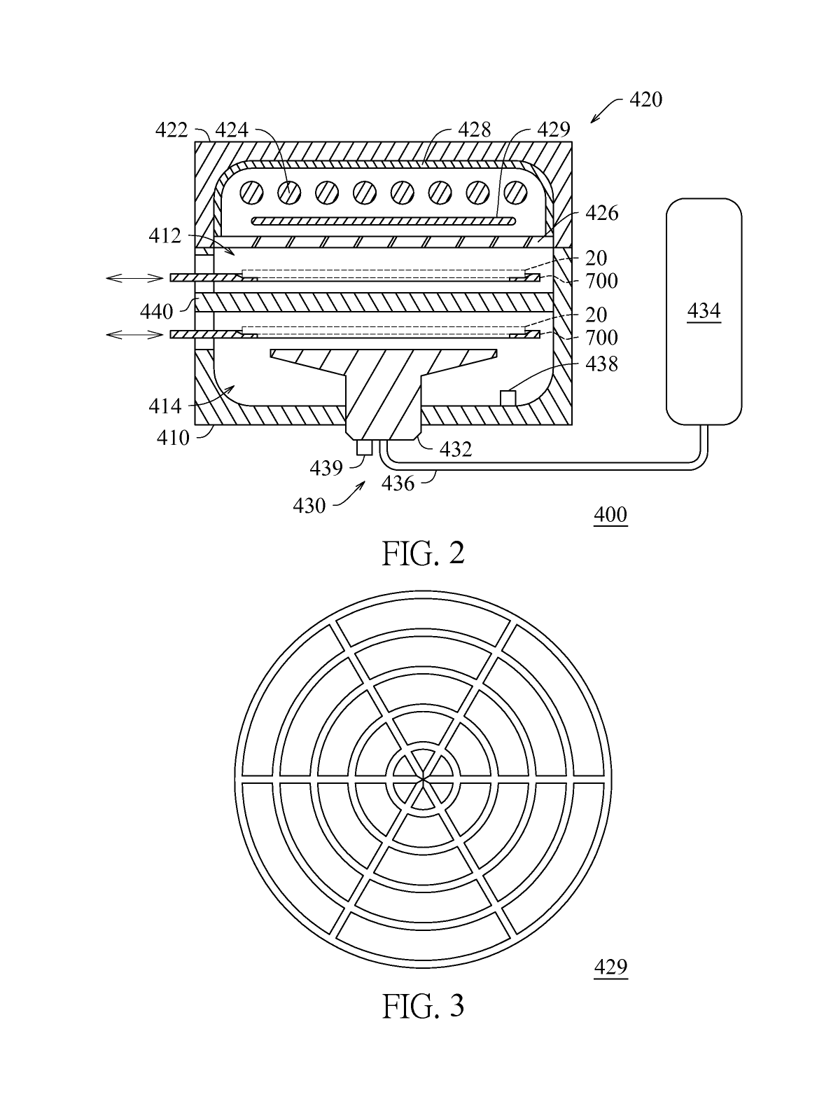

FIG. 1 illustrates a schematic view of an ion implanter according to an embodiment of the present invention. Moreover, FIG. 2 illustrates a cross-sectional view of the temperature treating assembly as shown in FIG. 2, while FIG. 3 illustrates a top view of the shield element as shown in FIG. 3. Referring to FIG. 1 first, an ion implanter 10 of the present invention comprises a FOUP 100, a first load lock 200, a VTM (vacuum transfer module) chamber 300, a temperature treating assembly 400, a process chamber 500 and a second load lock 600. A workpiece 20, for example but not limited to a silicon wafer, a glass plate and so on, can be transferred toward and away from the process chamber 500 for processing a recipe of an ion implantation. In brief, both of the first load lock 200 and the second load lock 600 are located between the FOUP 100 and the VTM chamber 300, wherein the first load lock 200 is used for passing the workpiece 20 from an ambient condition to a vacuum condition before the workpiece 20 is transferred into the VTM chamber 300, while the second load lock 600 is used for passing the workpiece 20 from a vacuum condition to an ambient condition after the workpiece 20 is transferred out of the VTM chamber 300. Furthermore, the VTM chamber 300 also communicates with the temperature treating assembly 400 and the process chamber 500, so as to enable the workpiece 20 to be transferred into either the temperature treating assembly 400 for a temperature treatment or the process chamber 500 for the recipe of the ion implantation with an arm 700 as shown in FIG. 2.

In detail, referring to FIGS. 1 and 2 together, the temperature treating assembly 400 is composed of a vacuum chamber 410, a heating module 420 and a cooling module 430. The vacuum chamber 410 communicates with the process chamber 500, for example via the VTM chamber 300, and has a heating space 412 and a cooling space 414 next to the heating space 412, for example under the heating space 412. In a specific embodiment, the heating space 412 can be separated from the cooling space 414 by using a partition 440. Furthermore, the heating module 420 is mounted on the vacuum chamber 410, for example covering a top side opening of the vacuum chamber 410, for heating the workpiece 20 located in the heating space 412, while the cooling module 430 is mounted in the cooling space 414, for example passing through a bottom side wall of the vacuum chamber 410, for cooling the workpiece 20 located in the cooling space 414.

As a result, for a recipe of a high temperature implantation, the workpiece 20 can be pre-heated to meet a required temperature of the recipe, for example significantly higher than the room temperature, before the workpiece 20 is implanted according to the recipe in the process chamber 500. Then, the workpiece 20 can further be post-cooled, for example to meet the room temperature, before being returned to the FOUP 100. In contrast, for a recipe of a low temperature implantation, the workpiece 20 can be pre-cooled to meet a required temperature of the recipe, for example significantly lower than the room temperature, before the workpiece 20 is implanted according to the recipe in the process chamber 500. Then, the workpiece 20 can further be post-heated, for example to meet the room temperature, before being returned to the FOUP 100.

In a specific embodiment, referring to FIGS. 2 and 3 together, the heating module 420 can be composed of a housing 422, at least a heater 424, a quartz window 426, a reflector 428 and a shield element 429. The housing 422 can covers the top side opening of the vacuum chamber 410. In addition, the heater 424 can be practiced by at least an IR lamp arranged in the housing 422 as shown in FIG. 2 or a heating wire, while the quartz window 426 covers the housing 422 for separating the heater 424 from the heating space 412. Furthermore, the reflector 428 is located on an inner surface of the housing 422, so as to reflect the heat flux provided by the heater 424 toward the quartz window 426. Besides, the shield element 429 can be practiced by a plurality of concentric circles connected to each other with a plurality of radial ribs as shown in FIG. 3, and is arranged between the heater 424 and the quartz window 426, so as to uniformly spread the heat flux provided by the heater 424 to pass through the quartz window 426 toward the workpiece 20.

In contrast, referring to FIG. 2, the cooling module 430 can be composed of an ESC 432, a chiller 434 and a coolant line 436. The ESC 432 can pass through the bottom side wall of the vacuum chamber 410 for holding the workpiece 20. Moreover, the chiller 434 is disposed outside the vacuum chamber 410, and the coolant line 436 connects the ESC 432 to the chiller 434. Hence, it is possible to chill the ESC 432 by the chiller 434 via the coolant line 436. In a specific embodiment, the cooling module 430 can further comprise a sensor 438 and a thermistor 439. The sensor 438 can be disposed in the cooling space 414 for detecting a position of the workpiece 20 in the vacuum chamber 410, while the thermistor 439 can be disposed on the ESC 432 for monitoring a temperature of the ESC 432.

According to the disclosure of the present invention described above, it is possible to previously and/or posteriorly adjust a temperature of a workpiece to meet a recipe of an ion implantation whether it is a high temperature implantation, a low temperature implantation or a normal temperature implantation, so as to significantly increase a throughput of the ion implantation. Also, since both of the heating module and the cooling module are integrated into a single vacuum chamber communicating with the VTM chamber, the total volume of the temperature treating assembly can be minimized as possible. Further, it is also possible to modify the conventional ion implantation procedure for improving the yielding rate of the manufacture by pre-cooling/pre-heating a workpiece at least one time and post-heating/post-cooling a workpiece at least one time. In order to help a person having ordinary skilled in the art to well understand the application of the ion implanter described herein, the disclosure further exemplarily illustrates some methods for an ion implantation hereinafter.

However, the ion implanter should not be limited to the application(s) of the following method(s). Similarly, the following method(s) for an ion implantation should not be limited to the usage(s) of the ion implanter(s) described above as well.

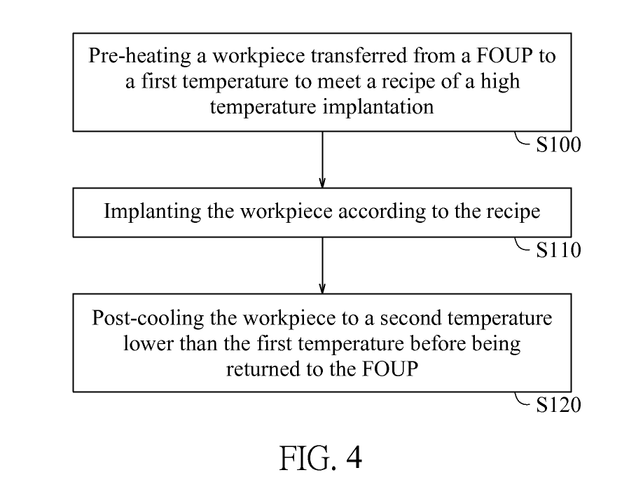

FIG. 4 illustrates a flow chart of a method for an ion implantation according to an embodiment of the present invention. Referring to FIG. 4, the method in this embodiment comprises the following steps. First, as shown in a block S100, a workpiece transferred from a FOUP is pre-heated to a first temperature to meet a required temperature of a recipe of a high temperature implantation. In a preferred embodiment, the step for pre-heating the workpiece can be treated in a heating space of a vacuum chamber communicating with a process chamber for the recipe and practiced by warming the workpiece by at least a heater, for example but not limited to at least an IR lamp or a heating wire. Further, in a preferred embodiment, the first temperature can be significantly higher than a room temperature. It should be noted that, in the case of pre-heating the workpiece in the vacuum chamber, the method should further comprise a step for passing the workpiece from an ambient condition to a vacuum condition in a load lock before the workpiece is transferred into the vacuum chamber for pre-heating.

Next, as shown in a block S110, the workpiece is implanted according to the recipe. Then, as shown in a block S 120, the workpiece is post-cooled to a second temperature lower than the first temperature before being returned to the FOUP. In a preferred embodiment, the step for post-cooling the workpiece can be treated in a cooling space of the vacuum chamber and practiced by chilling an ESC used for holding the workpiece by using a chiller via a coolant line connected therebetween. Further, in a preferred embodiment, the second temperature can be substantially equal to the room temperature. Similarly, in the case of post-cooling the workpiece in the vacuum chamber, the method should further comprise a step for passing the workpiece from a vacuum condition to an ambient condition in a load lock before the workpiece is returned to the FOUP.

In summary, by using the above-mentioned ion implanter(s) and/or method(s) for an ion implantation disclosed in the present disclosure, it is possible to achieve at least one of the following advantages, comprising but not limited to: pre-heating a workpiece to meet a recipe of a high temperature implantation before the workpiece is implanted, post-cooling a workpiece to meet the room temperature after the workpiece is implanted by a recipe of a high temperature implantation, pre-cooling a workpiece to meet a recipe of a low temperature implantation before the workpiece is implanted, post-heating a workpiece to meet the room temperature after the workpiece is implanted by a recipe of a low temperature implantation, significantly increasing a throughput of the ion implantation, modifying a conventional ion implantation procedure for improving the yielding rate of the manufacture by pre-cooling/pre-heating a workpiece at least one time and/or post-heating/post-cooling a workpiece at least one time, and so on.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. An ion implanter, comprising:
a process chamber, wherein a workpiece is capable of being implanted according to a recipe of an ion implantation therein;
a FOUP, capable of transferring a workpiece toward and away from the process chamber;
a temperature treating assembly, comprising:
a vacuum chamber, communicating with the process chamber and having a heating space and a cooling space next to the heating space;
a heating module, mounted on the vacuum chamber from a side of the heating space for heating the workpiece located in the heating space to a first temperature; and
a cooling module, mounted in the cooling space for cooling the workpiece located in the cooling space to a second temperature different from the first temperature.

2. The ion implanter as claimed in claim 1, further comprising a load lock located between the FOUP and the process chamber for passing the workpiece between an ambient condition and a vacuum condition.

3. The ion implanter as claimed in claim 1, further comprising an arm for transferring the workpiece between the process chamber and the vacuum chamber.

4. The ion implanter as claimed in claim 1, wherein the temperature treating assembly further comprises a partition for separating the heating space from the cooling space.

5. The ion implanter as claimed in claim 1, wherein the heating module comprises:
a housing;
at least a heater, arranged in the housing; and
a quartz window, covering the housing for separating the heater from the heating space.

6. The ion implanter as claimed in claim 5, wherein the heater comprises at least an IR lamp or a heating wire.

7. The ion implanter as claimed in claim 5, wherein the heating module further comprises a reflector located on an inner surface of the housing, so as to reflect the heat flux provided by the heater toward the quartz window.

8. The ion implanter as claimed in claim 5, wherein the heating module further comprises a shield element arranged between the heater and the quartz window, so as to spread the heat flux provided by the heater toward the quartz window.

9. The ion implanter as claimed in claim 1, wherein the cooling module comprises:
an ESC, mounted in the cooling space for holding the workpiece;
a chiller, disposed outside the vacuum chamber; and
a coolant line, connecting the ESC to the chiller, so as to chill the ESC by the chiller via the coolant line.

10. The ion implanter as claimed in claim 9, wherein the cooling module further comprises a thermistor disposed on the ESC for monitoring a temperature of the ESC.

11. The ion implanter as claimed in claim 1, wherein the cooling module further comprises a sensor disposed in the cooling space for detecting a position of the workpiece.

12. The ion implanter as claimed in claim 1, wherein one of the first temperature and the second temperature is treated to meet a requirement of the recipe before the workpiece is implanted, while the other one of the first temperature and the second temperature is treated to meet the room temperature before the workpiece is returned to the FOUP.

13. A method for an ion implantation, comprising:
pre-heating a workpiece transferred from a FOUP to a first temperature to meet a recipe of the ion implantation;
implanting the workpiece according to the recipe; and
post-cooling the workpiece to a second temperature lower than the first temperature before being returned to the FOUP.

14. The method as claimed in claim 13, wherein the first temperature is significantly higher than a room temperature, while the second temperature is substantially equal to the room temperature.

15. The method as claimed in claim 13, wherein the step for pre-heating the workpiece is treated in a heating space of a vacuum chamber communicating with a process chamber for the recipe.

16. The method as claimed in claim 13, wherein the step for pre-heating the workpiece comprises warming the workpiece by at least a heater.

17. The method as claimed in claim 16, wherein the heater comprises at least an IR lamp or a heating wire.

18. The method as claimed in claim 13, wherein the step for post-cooling the workpiece is treated in a cooling space of a vacuum chamber communicating with a process chamber for the recipe.

19. The method as claimed in claim 13, wherein the step for post-cooling the workpiece comprises chilling an ESC by a chiller via a coolant line connected therebetween.

20. The method as claimed in claim 13, further comprising passing the workpiece from an ambient condition to a vacuum condition in a load lock before pre-heating the workpiece.

21. The method as claimed in claim 13, further comprising passing the workpiece from a vacuum condition to an ambient condition in a load lock before returned the workpiece to the FOUP.

22. A method for an ion implantation, comprising:
warming a workpiece transferred from a FOUP by at least a heater, so as to pre-heat the workpiece to a first temperature to meet a recipe of the ion implantation;
transferring the workpiece to a process chamber for the recipe;
implanting the workpiece according to the recipe in the process chamber;
chilling an ESC by a chiller via a coolant line connected between the ESC and the chiller, so as to post-cool the workpiece to a second temperature lower than the first temperature; and
returning the workpiece to the FOUP.

23. The method as claimed in claim 22, wherein the first temperature is significantly higher than a room temperature, while the second temperature is substantially equal to the room temperature.

24. The method as claimed in claim 22, wherein the step for pre-heating the workpiece is treated in a heating space of a vacuum chamber communicating with the process chamber.

25. The method as claimed in claim 22, wherein the heater comprises at least an IR lamp or a heating wire.

26. The method as claimed in claim 22, wherein the step for post-cooling the workpiece is treated in a cooling space of a vacuum chamber communicating with the process chamber.

27. The method as claimed in claim 22, further comprising passing the workpiece from an ambient condition to a vacuum condition in a load lock before pre-heating the workpiece.

28. The method as claimed in claim 22, further comprising passing the workpiece from a vacuum condition to an ambient condition in a load lock before returned the workpiece to the FOUP.
